(19) United States
(12) Patent Application Publication
(10) Pub. No.: US 2017/0243855 A1
(43) Pub. Date: Aug. 24, 2017

(54) SEMICONDUCTOR PACKAGE

(71) Applicant: Samsung Electronics Co., Ltd., Suwon-si (KR)

(72) Inventor: Kil Soo KIM, Hwaseong-si (KR)

(73) Assignee: Samsung Electronics Co., Ltd., Suwon-si (KR)

(21) Appl. No.: 15/349,338

(22) Filed: Nov. 11, 2016

(30) Foreign Application Priority Data
Feb. 23, 2016 (KR) 10-2016-0020908

(51) Int. Cl. H01L 25/065; H01L 23/00; H01L 23/31

(52) U.S. Cl. CPC H01L 25/0652; H01L 23/3128; H01L 25/0657; H01L 24/49; H01L 24/09; H01L 2225/06506; H01L 2225/06541; H01L 2225/06517; H01L 2224/48091; H01L 2225/0651; H01L 2225/06589

(57) ABSTRACT

A semiconductor package including a mounting board, a first semiconductor chip on the mounting board, the first semiconductor chip having a first peripheral area, a second peripheral area, and a central area between the first and second peripheral areas, the central area having penetrating electrodes formed therein, a second semiconductor chip on the first peripheral area, the second semiconductor chip including a second pad on a top surface thereof, a third semiconductor chip on the second peripheral area, the third semiconductor chip including a third pad on a top surface thereof, and conductive wirings extending from the second and third pads, respectively, the conductive wirings electrically connected to the penetrating electrodes, respectively, may be provided.

This application claims priority to Korean Patent Application No. 10-2016-0020908 filed on Feb. 23, 2016 in the Korean Intellectual Property Office, the disclosure of which is incorporated herein by reference in its entirety.

### BACKGROUND

1. Technical Field

The present disclosure relates to semiconductor packages, and more particularly, to semiconductor packages in which a plurality of semiconductor chips are stacked.

2. Description of the Related Art

One of the goals in the semiconductor industry is to fabricate compact-size, multifunctional, large-capacity, and/or highly-reliable semiconductor products at lower cost. Semiconductor packaging technology plays an important role in achieving such goals. For example, a stacked semiconductor package, among other semiconductor packaging techniques, has been suggested to stack multiple chips in one package.

As the integration density and the storage capacity of semiconductor devices increase, three-dimensional (3D) packaging for stacking individual chips has been developed. For example, a through silicon via contact technique, which forms via holes that penetrate a substrate, and forms electrodes in the via holes, has been adopted as a type of 3D package structures that can replace an existing wire bonding technique.

### SUMMARY

Some example embodiments of the present disclosure provide semiconductor packages into which semiconductor chips can be highly integrated.

Some example embodiments of the present disclosure provide semiconductor packages with an improved degree of freedom as to the stacking of semiconductor chips.

Some example embodiments of the present disclosure provide semiconductor packages which are relatively easy to fabricate.

However, example embodiments of the present disclosure are not restricted to those set forth herein. The above and other example embodiments of the present disclosure will become more apparent to one of ordinary skill in the art to which the present disclosure pertains by referencing the detailed description of the present disclosure given below.

According to an example embodiment of the present disclosure, a semiconductor package includes a mounting board, a first semiconductor chip on the mounting board, the first semiconductor chip having a first peripheral area, a second peripheral area, and a central area between the first and second peripheral areas, the central area having penetrating electrodes formed therein, a second semiconductor chip on the first peripheral area, the second semiconductor chip including a second pad on a top surface thereof, a third semiconductor chip on the second peripheral area, the third semiconductor chip including a third pad on a top surface thereof, and conductive wirings extending from the second and third pads, respectively, the conductive wirings electrically connected to the penetrating electrodes, respectively.

According to another example embodiment of the present disclosure, a semiconductor package includes a mounting board, a first semiconductor chip on the mounting board, the first semiconductor chip including penetrating electrodes and first pads, the penetrating electrodes in the first semiconductor chip, and the first pads on the penetrating electrodes, respectively, second and third semiconductor chips on the first semiconductor chip. the second and third semiconductor chips spaced apart from each other to expose the first pads therebetween, the second and third semiconductor chips being devoid of through silicon vias, and conductive wirings electrically connecting the first, second, and third semiconductor chips.

According to another example embodiment of the present disclosure, a semiconductor package includes a mounting board, a first semiconductor chip on the mounting board, the first semiconductor chip including penetrating electrodes at a central area thereof, the penetrating electrodes electrically connecting the mounting board to the first semiconductor chip, at least one second semiconductor chip and at least one third semiconductor chip on the first semiconductor chip, the second semiconductor chip including a second pad on a top surface thereof, the third semiconductor chip including a third pad on a top surface thereof, the second and third semiconductor chips spaced apart from each other to expose the central area of the first semiconductor chip and conductive wirings respectively extending from the second and third pads, the conductive wirings respectively electrically connecting the second and third pads to the penetrating electrodes.

Other features and aspects will be apparent from the following detailed description, the drawings, and the claims.

### BRIEF DESCRIPTION OF THE DRAWINGS

FIG. 1 is a cross-sectional view of a semiconductor package according to an example embodiment of the present disclosure.

FIG. 2 is a cross-sectional view of a semiconductor package according to another example embodiment of the present disclosure.

FIG. 3 is a cross-sectional view of a semiconductor package according to another example embodiment of the present disclosure.

FIG. 4 is a cross-sectional view of a semiconductor package according to another example embodiment of the present disclosure.

FIG. 5 is a cross-sectional view of a semiconductor package according to another example embodiment of the present disclosure.

FIG. 6 is a cross-sectional view of a semiconductor package according to another example embodiment of the present disclosure.

FIG. 7 is a cross-sectional view of a semiconductor package according to another example embodiment of the present disclosure.

FIG. 8 is a cross-sectional view of a semiconductor package according to another example embodiment of the present disclosure.

FIG. 9 is a schematic diagram illustrating a memory card to which one or more semiconductor packages according to some example embodiments of the present disclosure are applied.

FIG. 10 is a block diagram of an electronic system to which one or more semiconductor packages according to some example embodiments of the present disclosure are applied.

FIG. 11 is a schematic view illustrating an example of the application of the electronic system of FIG. 10 to a smartphone.

### DETAILED DESCRIPTION

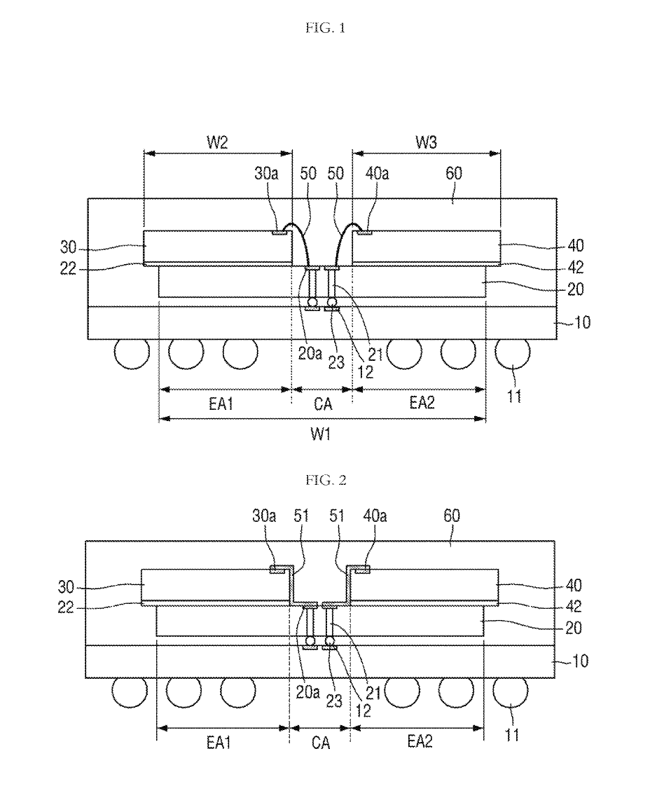

A semiconductor package according to an example embodiment of the present disclosure will hereinafter be described with reference to FIG. 1.

FIG. 1 is a cross-sectional view of a semiconductor package according to an example embodiment of the present disclosure.

Referring to FIG. 1, a semiconductor package according to the present example embodiment includes a mounting board 10, a first semiconductor chip 20, a second semiconductor chip 30, a third semiconductor chip 40, and a package molding part 60.

The first semiconductor chip 20 may be disposed on the mounting board 10. The second and third semiconductor chips 30 and 40 may be disposed on the first semiconductor chip 20. The package molding part 60 may be disposed on the mounting board 10 and may cover the first, second, and third semiconductor chips 20, 30, and 40.

The mounting board 10 may be a board for packaging, for example, a printed circuit board (PCB) or a ceramic substrate. The mounting board 10 may have a top surface and a bottom surface that are opposite to each other. That is, the first semiconductor chip 20 may be disposed on the top surface of the mounting board 10, and external terminals 11 may be formed on the bottom surface of the mounting board 10 to electrically connect the semiconductor package according to the present example embodiment to an external device. The external terminals 11 are illustrated as being provided as solder balls, but the present disclosure is not limited thereto. In some example embodiments, the external terminals 11 may be provided as a grid array (e.g., a pin grid array, a ball grid array, or a land grid array).

Bonding pads 12 may be disposed on the top surface of the mounting board 10. The bonding pads 12 may be electrically connected to external terminals connected to an external device, and may supply electrical signals to the first semiconductor chip 20. The bonding pads 12 may also supply electrical signals to the second and third semiconductor chips 30 and 40.

At least one of the bonding pads 12 may be, for example, a ground pad, and may be electrically connected to a ground line in the mounting board 10. The bonding pads 12 may be disposed at, for example, the center of the mounting board 10, but the present disclosure is not limited thereto.

The first, second, and third semiconductor chips 20, 30, and 40 may be disposed on the mounting board 10. The first semiconductor chip 20 may be disposed directly on the mounting board 10, and the second and third semiconductor chips 30 and 40 may be disposed on the first semiconductor chip 10.

The first, second, and third semiconductor chips 20, 30, and 40 may be, for example, memory chips or logic chips. If the first, second, and third semiconductor chips 20, 30, and 40 are logic chips, the first, second, and third semiconductor chips 20, 30, and 40 may be designed in various manners in consideration of the types of operations performed by the first, second, and third semiconductor chips 20, 30, and 40. The logic chips may be micro-processors (e.g., central processing units (CPUs), controllers, or application-specific integrated circuits (ASICs)).

The first, second, and third semiconductor chips 20, 30, and 40 may be memory chips, for example, non-volatile memory chips. For example, the memory chips may be flash memory chips. More specifically, the memory chips may be NAND flash memory chips or NOR flash memory chips, but the present disclosure is not limited thereto. That is, examples of the memory chips may also include phase-change random access memories (PRAMs), magneto-resistive random access memories (MRAMs), or resistive random access memories (RRAMs).

The first semiconductor chip 20 may be of a different type from the second and third semiconductor chips 30 and 40. For example, the first semiconductor chip 20 may be a logic chip such as a mobile CPU, and the second and third semiconductor chips 30 and 40 may be memory chips (e.g., dynamic random access memories (DRAMs), wide input/output (I/O) DRAMs, flash memories, or PRAMs). However, the present disclosure is not limited to this example.

The first semiconductor chip 20 includes penetrating electrodes 21, which penetrate the first semiconductor chip 20. The first semiconductor chip 20 further includes first pads 20a, which are formed on the top surface of the first semiconductor chip 20, and first terminals 23, which are formed on the bottom surface of the first semiconductor chip 20. The first pads 20a and the first terminals 23 may be connected by the penetrating electrodes 21, which penetrate the first semiconductor chip 20. FIG. 1 illustrates two penetrating electrodes 21 as being formed in the first semiconductor chip 20, but the present disclosure is not limited thereto.

The penetrating electrodes 21 penetrate the first semiconductor chip 20. Each of the penetrating electrodes 21 may have a structure in which an insulating layer (not shown), a seed layer (not shown), and a conductive layer (not shown) are sequentially formed. The insulating layer may electrically insulate the conductive layer. The insulating layer may comprise, for example, an oxide, a nitride, or an oxynitride. More specifically, the insulating layer may comprise, for example, silicon oxide, silicon nitride, or silicon oxynitride. The conductive layer may comprise a conductive material such as metal. Examples of the metal that forms the penetrating electrodes 21 include, for example, aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), or zirconium (Zr), but the present disclosure is not limited thereto.

The insulating layer, the seed layer, and the conductive layer of each of the penetrating electrodes 21 may be formed by chemical vapor deposition (CVD), plasma-enhanced CVD (PECVD), high-density plasma CVD (HDP CVD), sputtering, metal organic CVD (MOCVD), or atomic layer deposition (ALD), but the present disclosure is not limited thereto.

The first semiconductor chip 20 may be electrically connected to the mounting board 10 via the first terminals 23, which are formed on the bonding pads 12. That is, the first terminals 23 may electrically connect the penetrating electrodes 21 of the first semiconductor chip 20 and the bonding pads 12 of the mounting board 10. The first terminals 23 are illustrated as being provided as solder balls, but the present disclosure is not limited thereto. That is, the first terminals 23 may be provided as solder bumps, which are a combination of pillars and solder balls.

For example, the first semiconductor chip 20 may be a flip chip, and the first terminals 23 may be formed on the surface where a semiconductor circuit device is formed. However, the present disclosure is not limited to this example. The first semiconductor chip 20 may include a passive device (e.g., a capacitor, an inductor, or a resistor). The first semiconductor chip 20 may include an electro-static discharge (ESD) prevention circuit.

In a case in which the first semiconductor chip 20 includes an ESD prevention circuit, the second and third semiconductor chips 30 and 40 may be formed to not include an ESD prevention circuit. When the second and third semiconductor chips 30 and 40 do not include any ESD prevention circuit, the semiconductor package according to some example embodiments can be miniaturized and may consume less power.

In FIG. 1, only the first semiconductor chip 20 is illustrated as including the penetrating electrodes 21, but the present disclosure is not limited thereto.

The first semiconductor chip 20 may have a first peripheral area EA1, a central area CA, and a second peripheral area EA2. The central area CA may be disposed between the first and second peripheral areas EA1 and EA2. The first peripheral area EA1, the central area CA, and the second peripheral area EA2 may be continuous to one another or may be separate and spaced apart from one another. The first semiconductor chip 20 may have a first length W1.

The first semiconductor chip 20 includes the penetrating electrodes 21, which are formed in the central area CA. The second semiconductor chip 30 may be disposed on the first peripheral area EA1 of the first semiconductor chip 20. The third semiconductor chip 40 may be disposed on the second peripheral area EA2 of the first semiconductor chip 20. Because the second and third semiconductor chips 30 and 40 are spaced apart from each other over the first semiconductor chip 20, the top surface of the central area CA of the first semiconductor chip 20 may be exposed. Also, the first pads 20a of the first semiconductor chip 20 may be exposed between the second and third semiconductor chips 30 and 40.

Referring again to FIG. 1, part of the second semiconductor chip 30 may be exposed over the first semiconductor chip 20. That is, part of the second semiconductor chip 30 may not overlap the first semiconductor chip 20. Also, part of the third semiconductor chip 40 may be exposed over the first semiconductor chip 20. That is, part of the third semiconductor chip 40 may not overlap the first semiconductor chip 20.

The second and third semiconductor chips 30 and 40, unlike the first semiconductor chip 20, may not include any through silicon via. That is, the first semiconductor chip 20 includes the penetrating electrodes 21, but the semiconductor chips stacked on the first semiconductor chip 20, e.g., the second and third semiconductor chips 30 and 40, may not include the penetrating electrodes 21 or any equivalents thereof. Thus, the degree of freedom as to the stacking of semiconductor chips on the first semiconductor chip 20 may be improved.

The first peripheral area EA1, the central area CA, and the second peripheral area EA2 are illustrated in FIG. 1 as being clearly distinguishable from one another, as indicated by dotted lines, but the present disclosure is not limited thereto. That is, the first peripheral area EA of the first semiconductor chip 20 may refer to an area of overlap between the first and second semiconductor chips 20 and 30. Also, the second peripheral area EA2 of the first semiconductor chip 20 may refer to an area of overlap between the first and third semiconductor chips 20 and 40. Also, the central area CA of the first semiconductor chip 20 may refer to an area of the first semiconductor chip 20 including the penetrating electrodes 21.

The second semiconductor chip 30 may be disposed on the first peripheral area EA1 of the first semiconductor chip 20. The second semiconductor chip 30 may be electrically connected to the first semiconductor chip 20. That is, a second pad 30a, which is formed on the second semiconductor chip 30, may be connected to one of the first pads 20a of the first semiconductor chip 20 via one conductive wiring 50. Thus, the second semiconductor chip 30 may be electrically connected to the first semiconductor chip 20. The conductive wirings 50 may be wires, but the present disclosure is not limited thereto. The second semiconductor chip 30 may have a second length W2.

The third semiconductor chip 40 may be disposed on the second peripheral area EA2 of the first semiconductor chip 20. The third semiconductor chip 40 may be electrically connected to the first semiconductor chip 20. That is, a third pad 40a, which is formed on the third semiconductor chip 40, may be connected via another conductive wiring 50 to the another of the first pads 20a that is not connected to the second pad 30a. Thus, the third semiconductor chip 40 may be electrically connected to the first semiconductor chip 20. The third semiconductor chip 40 may have a third length W3.

As described above, the first semiconductor chip 10 may have the first length W1, the second semiconductor chip 30 may have the second length W2, and the third semiconductor chip 40 may have the third length W3. The first length W1 may be longer than the second length W2. The first length W1 may be longer the third length W3. The second and third lengths W2 and W3 may be identical, but the present disclosure is not limited thereto. The sum of the second and third lengths W2 and W3 may be the same as the first length W1, but the present disclosure is not limited thereto.

For example, the second and third semiconductor chips 30 and 40 may be obtained by dividing a substrate including a plurality of semiconductor chip areas. That is, if the first semiconductor chip 20 includes at least two separate semiconductor chip areas, the second semiconductor chip 30 having the second length W2 and the third semiconductor chip 40 having the third length W3 may be obtained by physically separating the semiconductor chip areas of the first semiconductor chip 20, in which case, the sum of the second and third lengths W2 and W3 may be the same as the first length W1. If the second and third lengths W2 and W3 are identical, the first and second peripheral areas EA1 and EA2 may be symmetrical with each other with respect to the central area CA.

The second and third semiconductor chips 30 and 40 may have the same height, and the top surfaces of the second and third semiconductor chips 30 and 40 may be disposed on the same plane.

The first, second, and third semiconductor chips 20, 30, and 40 may all be DRAM semiconductor chips. For example, if the first semiconductor chip 20 includes two independent semiconductor chip areas, the semiconductor package according to an example embodiment of the present example embodiment may substantially be a semiconductor package including four DRAM semiconductor chips.

The first, second, and third semiconductor chips 20, 30, and 40, which are disposed on the mounting board 10, may be surrounded by the package molding part 60. By using the package molding part 60, the space between the first semiconductor chip 20 and the mounting board 10 may be filled. The package molding part 60 may comprise, for example, an epoxy molding compound (EMC) or polyimide, but the present disclosure is not limited thereto.

Insulating adhesive layers 22 may be disposed between the first and second semiconductor chips 20 and 30 and between the first and third semiconductor chips 20 and 40. By using the insulating adhesive layers 22, the second semiconductor chip 30 may be attached onto the first semiconductor chip 20, and the third semiconductor chip 40 may be attached onto the first semiconductor chip 20. The insulating adhesive layers 22 may comprise an insulating material. The insulating adhesive layers 22 may be disposed on the entire bottom surfaces of the second and third semiconductor chips 30 and 40, but the present disclosure is not limited thereto. That is, one of the insulating adhesive layers 22 may be disposed only on part of the bottom surface of the second semiconductor chip 30 in the area of overlap between the first and second semiconductor chips 20 and 30. Also, the other insulating adhesive layer 22 may be disposed only on part of the bottom surface of the third semiconductor chip 40 in the area of overlap between the first and third semiconductor chips 20 and 40.

The insulating adhesive layers 22 may be, for example, die attach films (DAFs), but the present disclosure is not limited thereto.

A semiconductor package according to another example embodiment of the present disclosure will hereinafter be described with reference to FIG. 2.

FIG. 2 is a cross-sectional view of a semiconductor package according to another example embodiment of the present disclosure.

The semiconductor package according to the example embodiment of FIG. 2 is substantially the same as the semiconductor package according to the example embodiment of FIG. 1, except for the type of conductive wirings. In FIGS. 1 and 2, like reference numerals indicate like elements, and thus, detailed descriptions thereof will be omitted.

Referring to FIG. 2, the semiconductor package according to the present example embodiment includes a mounting board 10, a first semiconductor chip 20, a second semiconductor chip 30, a third semiconductor chip 40, and a package molding part 60.

The second and third semiconductor chips 30 and 40 may be electrically connected to the first semiconductor chip 20 via conductive wirings 51.

For example, one of the conductive wirings 51 may extend from the top surface of a second pad 30a of the second semiconductor chip 30 along the top surface and the sidewall of the second semiconductor chip 30 and the top surface of the first semiconductor chip 20 to contact the top surface of a first pad 20a of the first semiconductor chip 20. Thus, the second semiconductor chip 30 may be electrically connected to the first semiconductor chip 20.

The other one of the conductive wirings 51 may extend from the top surface of a third pad 40a of the third semiconductor chip 40 along the top surface and the sidewall of the third semiconductor chip 40 and the top surface of the first semiconductor chip 20 to contact the top surface of another first pad 20a of the first semiconductor chip 20. Thus, the third semiconductor chip 40 may be electrically connected to the first semiconductor chip 20.

The conductive wirings 51 may be formed of a conductive material including Cu.

Because the conductive wirings 51 extend along the top surfaces and the sidewalls of the second and third semiconductor chips 30 and 40, the semiconductor package according to the present example embodiment can be further miniaturized, compared to a case in which the conductive wirings 51 are provided as wires.

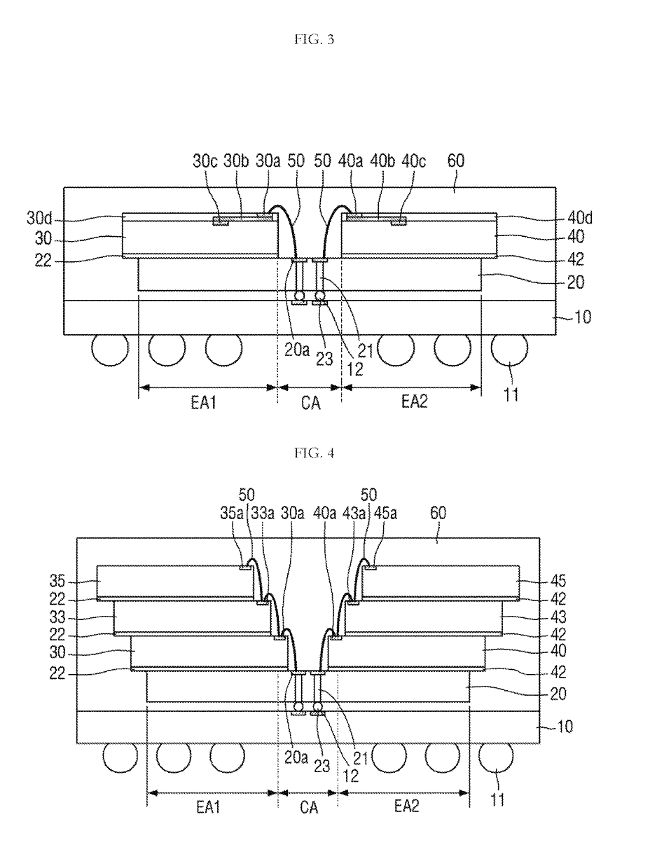

A semiconductor package according to another example embodiment of the present disclosure will hereinafter be described with reference to FIG. 3.

FIG. 3 is a cross-sectional view of a semiconductor package according to another example embodiment of the present disclosure.

The semiconductor package according to the example embodiment of FIG. 3 is substantially the same as the semiconductor package according to the example embodiment of FIG. 1, except that it further includes rewiring layers. In FIGS. 1 and 3, like reference numerals indicate like elements, and thus, detailed descriptions thereof will be omitted.

Referring to FIG. 3, the semiconductor package according to the present example embodiment includes a mounting board 10, a first semiconductor chip 20, a second semiconductor chip 30, a third semiconductor chip 40, and a package molding part 60.

The second semiconductor chip 30 includes a second center pad 30c, a second rewiring layer 30b, a second pad 30a, and a second insulating layer 30d. The second rewiring layer 30b may electrically connect the second center pad 30c and the second pad 30a. The second insulating layer 30d may cover the entire top surface of the second semiconductor chip 30, except for the top surface of the second pad 30a.

The third semiconductor chip 40 includes a third center pad 40c, a third rewiring layer 40b, a third pad 40a, and a third insulating layer 40d. The third rewiring layer 40b may electrically connect the third center pad 40c and the third pad 40a. The third insulating layer 40d may cover the entire top surface of the third semiconductor chip 40, except for the top surface of the third pad 40a.

Because the second and third semiconductor chips 30 and 40 include the second and third rewiring layers 30b and 40b, respectively, the locations of the second and third pads 30a and 40a can be freely designed.

A semiconductor package according to another example embodiment of the present disclosure will hereinafter be described with reference to FIG. 4.

FIG. 4 is a cross-sectional view of a semiconductor package according to another example embodiment of the present disclosure.

The semiconductor package according to the example embodiment of FIG. 4 is substantially the same as the semiconductor package according to the example embodiment of FIG. 1, except for the number of semiconductor chips stacked. In FIGS. 1 and 4, like reference numerals indicate like elements, and thus, detailed descriptions thereof will be omitted.

Referring to FIG. 4, the semiconductor package according to the present example embodiment includes a mounting board 10, a first semiconductor chip 20, a second semiconductor chip 30, a third semiconductor chip 40, and a package molding part 60.

The semiconductor package according to the present example embodiment may further include a fourth semiconductor chip 33 and a sixth semiconductor chip 35, which are disposed on the second semiconductor chip 30. The semiconductor package according to the present example embodiment may further include a fifth semiconductor chip 43 and a seventh semiconductor chip 45, which are disposed on the third semiconductor chip 40.

The fourth, fifth, sixth, and seventh chips 33, 43, 35, and 45 may be, for example, memory chips or logic chips. In a case in which the fourth, fifth, sixth, and seventh chips 33, 43, 35, and 45 are logic chips, the fourth, fifth, sixth, and seventh chips 33, 43, 35, and 45 may be designed in various manners in consideration of the types of operations performed by the first, second, and third semiconductor chips 20, 30, and 40. The logic chips may be micro-processors (e.g., CPUs, controllers, or ASICs).

The fourth, fifth, sixth, and seventh chips 33, 43, 35, and 45 may be memory chips, for example, non-volatile memory chips. For example, the memory chips may be flash memory chips. More specifically, the memory chips may be NAND flash memory chips or NOR flash memory chips, but the present disclosure is not limited thereto. That is, examples of the memory chips may include PRAMs, MRAMs, or RRAMs.

The fourth, fifth, sixth, and seventh chips 33, 43, 35, and 45, unlike the first semiconductor chip 20, may not include penetrating electrodes.

The fourth and sixth semiconductor chips 33 and 35 may include a fourth pad 33a and a sixth pad 35a, respectively. The fourth and sixth semiconductor chips 33 and 35 may be disposed on the second semiconductor chip 30 in a stepped manner such that the fourth and sixth pads 33a and 35a can be exposed. The fourth and sixth pads 33a and 35a, which are exposed, may be connected to conductive wirings 50, respectively. Thus, the fourth and sixth semiconductor chips 33 and 35 may be electrically connected to the first semiconductor chip 20.

The fifth and seventh semiconductor chips 43 and 45 may include a fifth pad 43a and a seventh pad 45a, respectively. The fifth and seventh semiconductor chips 43 and 45 may be disposed on the third semiconductor chip 40 in a stepped manner such that the fifth and seventh pads 43a and 45a can be exposed. The fifth and seventh pads 43a and 45a, which are exposed, may be connected to conductive wirings 50, respectively. Thus, the fifth and seventh semiconductor chips 43 and 45 may be electrically connected to the first semiconductor chip 20.

The second and third semiconductor chips 30 and 40 are illustrated as having the same number of semiconductor chips stacked thereon, but the present disclosure is not limited thereto. That is, the number of semiconductor chips stacked on the second semiconductor chip 30 may differ from the number of semiconductor chips stacked on the third semiconductor chip 40.

Each of the second and third semiconductor chips 30 and 40 are illustrated as having two semiconductor chips stacked thereon, but the present disclosure is not limited thereto. That is, more than two semiconductor chips may be stacked on each of the second and third semiconductor chips 30 and 40.

A semiconductor package according to another example embodiment of the present disclosure will hereinafter be described with reference to FIG. 5.

FIG. 5 is a cross-sectional view of a semiconductor package according to another example embodiment of the present disclosure.

The semiconductor package according to the example embodiment of FIG. 5 is substantially the same as the semiconductor package according to the example embodiment of FIG. 4, except for the type of conductive wirings. In FIGS. 4 and 5, like reference numerals indicate like elements, and thus, detailed descriptions thereof will be omitted.

Referring to FIG. 5, the semiconductor package according to the present example embodiment includes a mounting board 10, a first semiconductor chip 20, a second semiconductor chip 30, a third semiconductor chip 40, and a package molding part 60. The semiconductor package according to the present example embodiment may further include a fourth semiconductor chip 33 and a sixth semiconductor chip 35, which are disposed on the second semiconductor chip 30. The semiconductor package according to the present example embodiment may further include a fifth semiconductor chip 43 and a seventh semiconductor chip 45, which are disposed on the third semiconductor chip 40.

The second, fourth, and sixth semiconductor chips 30, 33, and 35 may be electrically connected to the first semiconductor chip 20 via a conductive wiring 51. The conductive wiring 51 may extend from a sixth pad 35a of the sixth semiconductor chip 35 along the top surface and the sidewall of the sixth semiconductor chip 35, and thus may be connected to a fourth pad 33a of the fourth semiconductor chip 33. Then, the conductive wiring 51 may extend from the fourth pad 33a of the fourth semiconductor chip 33 along the top surface and the sidewall of the fourth semiconductor chip 33, and thus may be connected to a second pad 30a of the second semiconductor chip 30. Then, the conductive wiring 51 may extend from the second pad 30a of the second semiconductor chip 30 along the top surface and the sidewall of the second semiconductor chip 30, and thus may be connected to a first pad 20a of the first semiconductor chip 20.

Similarly, the third, fifth, and seventh semiconductor chips 40, 43, and 45 may be electrically connected to the first semiconductor chip 20 via another conductive wiring 51. The conductive wiring 51 may extend from a seventh pad 45a of the seventh semiconductor chip 45 along the top surface and the sidewall of the seventh semiconductor chip 45, and thus may be electrically connected to a fifth pad 43a of the fifth semiconductor chip 43. Then, the conductive wiring 51 may extend from the fifth pad 43a of the fifth semiconductor chip 43 along the top surface and the sidewall of the fifth semiconductor chip 43, and thus may be electrically connected to a third pad 40a of the third semiconductor chip 40. Then, the conductive wiring 51 may extend from the third pad 40a of the third semiconductor chip 40 along the top surface and the sidewall of the third semiconductor chip 40, and thus may be electrically connected to another first pad 20a of the first semiconductor chip 20.

Because the semiconductor package according to the present example embodiment include the conductive wirings 51, which extend along the top surfaces and the sidewalls of the second, third, fourth, fifth, sixth, and seventh semiconductor chips 30, 40, 33, 43, 35, and 45, the semiconductor package according to the present example embodiment can be further miniaturized.

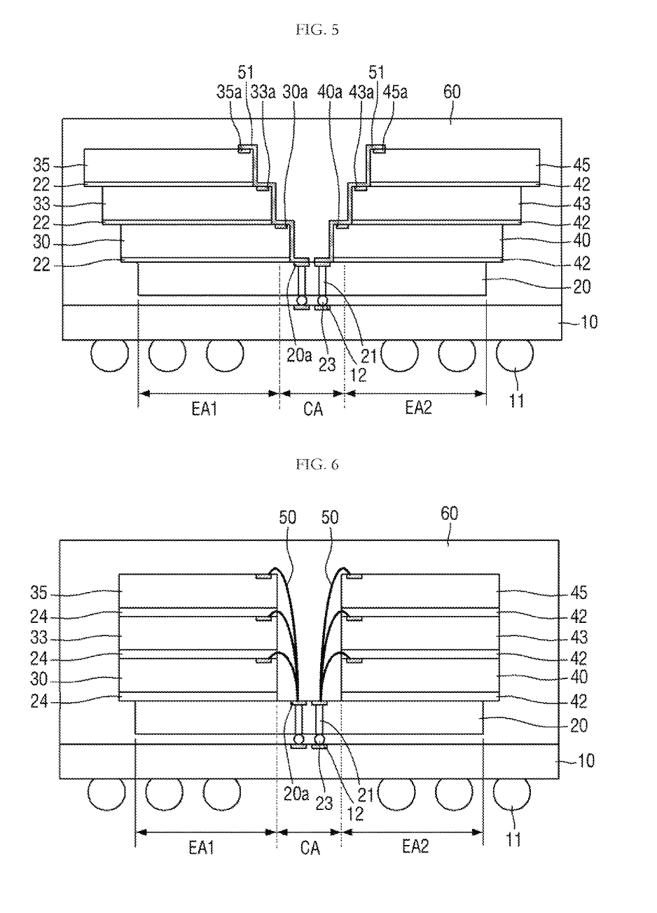

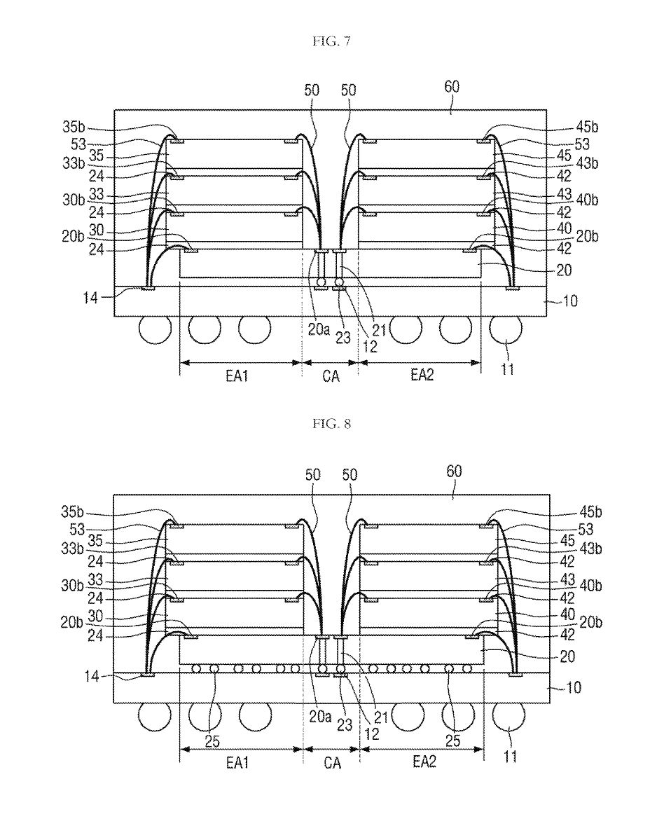

A semiconductor package according to another example embodiment of the present disclosure will hereinafter be described with reference to FIG. 6.

FIG. 6 is a cross-sectional view of a semiconductor package according to another example embodiment of the present disclosure.

The semiconductor package according to the example embodiment of FIG. 6 is substantially the same as the semiconductor package according to the example embodiment of FIG. 4, except that semiconductor chips are not stacked in a stepped manner. In FIGS. 4 and 6, like reference numerals indicate like elements, and thus, detailed descriptions thereof will be omitted.

Referring to FIG. 6, the semiconductor package according to the present example embodiment includes a mounting board 10, a first semiconductor chip 20, a second semiconductor chip 30, a third semiconductor chip 40, and a package molding part 60. The semiconductor package according to the present example embodiment may further include a fourth semiconductor chip 33 and a sixth semiconductor chip 35, which are disposed on the second semiconductor chip 30. The semiconductor package according to the present example embodiment may further include a fifth semiconductor chip 43 and a seventh semiconductor chip 45, which are disposed on the third semiconductor chip 40.

The fourth and sixth semiconductor chips 33 and 35, which are disposed on the second semiconductor chip 30, may be aligned with each other without forming any stepped structure on the sides thereof. Also, the fifth and seventh semiconductor chips 43 and 45, which are disposed on the third semiconductor chip 40, may be aligned with each other without forming any stepped structure on the sides thereof.

Because pads need to be connected to conductive wirings 50 via insulating adhesive layers 24, the insulating adhesive layers 24 may be formed to be relatively thicker than the insulating adhesive layers 22 included in any one of the semiconductor packages according to the previous example embodiments, but the present disclosure is not limited thereto.

The insulating adhesive layers 24 may be, for example, DAFs, but the present disclosure is not limited thereto.

In the semiconductor package according to the present example embodiment, semiconductor chips can be stacked with their sides aligned so as not to form any stepped structures. Thus, because the length of the semiconductor package according to the present example embodiment in the lengthwise direction of the semiconductor chips can be reduced, compared to the semiconductor packages according to the previous example embodiments. Accordingly, the semiconductor package according to the present example embodiment can be further miniaturized.

A semiconductor package according to another example embodiment of the present disclosure will hereinafter be described with reference to FIG. 7.

FIG. 7 is a cross-sectional view of a semiconductor package according to another example embodiment of the present disclosure.

The semiconductor package according to the example embodiment of FIG. 7 is substantially the same as the semiconductor package according to the example embodiment of FIG. 6, except that it further includes additional conductive wirings and edge pads. In FIGS. 6 and 7, like reference numerals indicate like elements, and thus, detailed descriptions thereof will be omitted.

Referring to FIG. 7, the semiconductor package according to the present example embodiment includes a mounting board 10, a first semiconductor chip 20, a second semiconductor chip 30, a third semiconductor chip 40, and a package molding part 60. The semiconductor package according to the present example embodiment may further include a fourth semiconductor chip 33 and a sixth semiconductor chip 35, which are disposed on the second semiconductor chip 30. The semiconductor package according to the present example embodiment may further include a fifth semiconductor chip 43 and a seventh semiconductor chip 45, which are disposed on the third semiconductor chip 40.

The first semiconductor chip 20 may include first edge pads 20b. The second semiconductor chip 30 may include a second edge pad 30b. The third semiconductor chip 40 may include a third edge pad 40b. The fourth semiconductor chip 33 may include a fourth edge pad 33b. The fifth semiconductor chip 43 may include a fifth edge pad 43b. The sixth semiconductor chip 35 may include a sixth edge pad 35b. The seventh semiconductor chip 45 may include a seventh edge pad 45b.

The first, second, third, fourth, fifth, sixth, and seventh edge pads 20b, 30b, 40b, 33b, 43b, 35b, and 45b may be electrically connected to edge bonding pads 14, which are disposed on the mounting board 10, via conductive wirings 53.

For example, the semiconductor package according to the present example embodiment may be supplied with additional power via the first, second, third, fourth, fifth, sixth, and seventh edge pads 20b, 30b, 40b, 33b, 43b, 35b, and 45b. Thus, the semiconductor package according to the present example embodiment may improve the stability of the supply of power.

However, the present disclosure is not limited to this example. That is, additional data signals may be input or output via the first, second, third, fourth, fifth, sixth, and seventh edge pads 20b, 30b, 40b, 33b, 43b, 35b, and 45b.

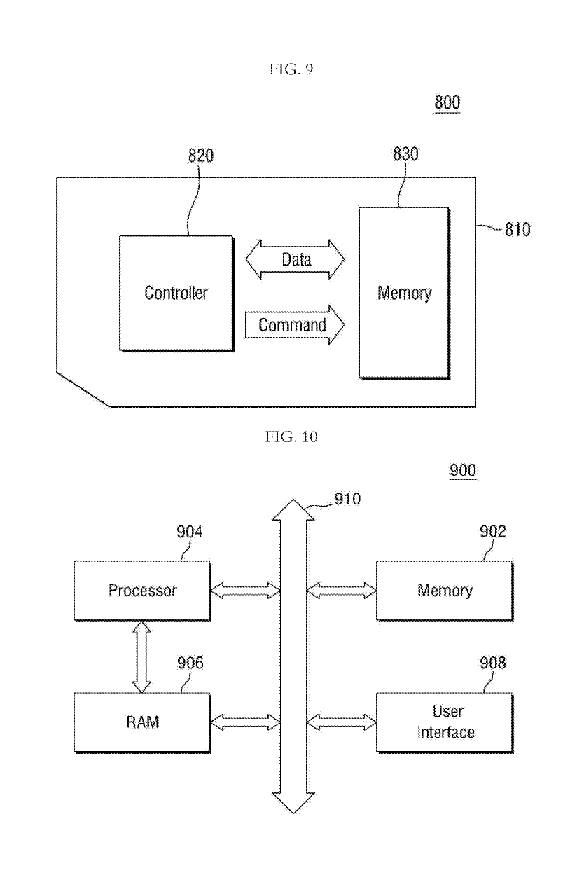

A semiconductor package according to another example embodiment of the present disclosure will hereinafter be described with reference to FIG. 8.

FIG. 8 is a cross-sectional view of a semiconductor package according to another example embodiment of the present disclosure.

The semiconductor package according to the example embodiment of FIG. 8 is substantially the same as the semiconductor package according to the example embodiment of FIG. 7, except that it further includes additional terminals below a first semiconductor chip. In FIGS. 7 and 8, like reference numerals indicate like elements, and thus, detailed descriptions thereof will be omitted.

Referring to FIG. 8, the semiconductor package according to the present example embodiment includes a mounting board 10, a first semiconductor chip 20, a second semiconductor chip 30, a third semiconductor chip 40, and a package molding part 60. The semiconductor package according to the present example embodiment may further include a fourth semiconductor chip 33 and a sixth semiconductor chip 35, which are disposed on the second semiconductor chip 30. The semiconductor package according to the present example embodiment may further include a fifth semiconductor chip 43 and a seventh semiconductor chip 45, which are disposed on the third semiconductor chip 40.

The first semiconductor chip 20 may further include additional terminals 25. By providing the additional terminals 25 in addition to first terminals 23, heat generated by the first semiconductor chip 20 can be effectively dissipated. Thus, the reliability of the semiconductor package according to the present example embodiment can be improved.

The additional terminals 25 may comprise a material with a high heat conductivity. The additional terminals 25 may be provided as, for example, metal plates or metal foils. More specifically, the additional terminals 25 may be provided as, for example, Cu plates, Al plates, Cu foils, Al foils, or a combination thereof, but the present disclosure is not limited thereto.

FIG. 9 is a schematic diagram illustrating a memory card to which one or more semiconductor packages according to some example embodiments of the present disclosure are applied.

Referring to FIG. 9, a memory card 800 may include a controller 820 and a memory 830 in a housing 810. The controller 820 and the memory 830 may exchange electrical signals. For example, the memory 830 and the controller 820 may exchange data according to a command of the controller 820. Accordingly, the memory card 800 may store data in the memory 830 or output data from the memory 830.

The controller 820 or the memory 830 may include semiconductor packages according to some example embodiments of the present disclosure. For example, the controller 820 may include a system in package (SIP), and the memory 830 may include a multi-chip package (MCP). The controller 820 and/or the memory 830 may be provided as a stack package (SP).

The memory card 800 may be used as a data storage medium for various portable devices. Examples of the memory card 800 may include a multimedia card (MMC) and a secure digital (SD) card.

FIG. 10 is a block diagram of an electronic system to which one or more semiconductor packages according to some example embodiments of the present disclosure are applied.

Referring to FIG. 10, an electronic system 900 may employ the semiconductor packages according to the above-described example embodiments of the present disclosure. For example, the electronic system 900 may include a memory system 902, a processor 904, a RAM 906, and a user interface 908.

The memory system 902, the processor 904, the RAM 906, and the user interface 908 may communicate data with one another via a bus 910.

The processor 904 may execute programs, and may control the electronic system 900. The RAM 906 may be used as an operating memory for the processor 904. The processor 904 and the RAM 906 may be packaged into a single semiconductor device or a single semiconductor package using a method of fabricating any one of the semiconductor packages according to the above-described example embodiments of the present disclosure.

The user interface 908 may be used to input data to or output data from the electronic system 900. The memory system 902 may store code for the operation of the processor 914 and may also store data processed by the processor 904 or data input thereto from an external source.

The memory system 902 may include a controller to drive the memory system 902, and may also include an error correction block (not shown). The error correction block may be configured to detect error from data present in the memory system 902 by means of error correction code (ECC) and to correct the detected error.

The memory system 902 may be integrated into a single semiconductor device. The memory system 902 may be integrated into a single semiconductor device so as to form a memory card. For example, the memory system 902 may be integrated into a single semiconductor device so as to form a memory card such as a PC memory card international association (PCMCIA) card, a compact flash (CF) card, a smart media (SM) card such as SMC), a memory stick, a multimedia card (MMC) (such as RS-MMC or MMCmicro), a secure digital (SD) card (such as miniSD, microSC or SDHC), or a universal flash storage (UFS).

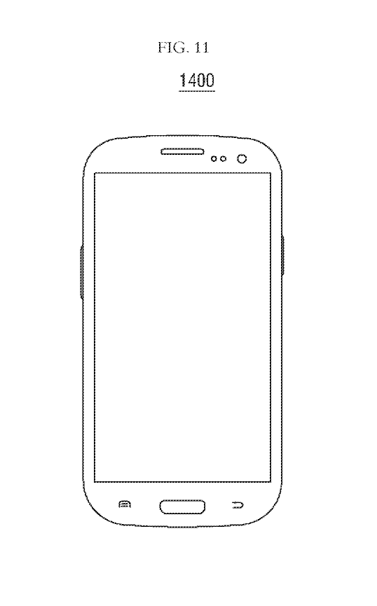

The electronic system 900 of FIG. 19 may be applied to electronic control devices for various electronic devices. FIG. 11 is a schematic view illustrating an example of the application of the electronic system 900 of FIG. 10 to a smartphone 1400. In a case in which the electronic system 900 of FIG. 10 is applied to the smartphone 1000, the electronic system 900 of FIG. 10 may be, but is not limited to, an application processor (AP).

The electronic system 900 of FIG. 10 may be provided as a computer, an Ultra Mobile PC (UMPC), a work station, a net-book computer, a Personal Digital Assistant (PDA), a portable computer, a web tablet, a wireless phone, a mobile phone, a smart phone, an e-book, a portable multimedia player (PMP), a portable game console, a navigation device, a black box, a digital camera, a 3-dimensional television set, a digital audio recorder, a digital audio player, a digital picture recorder, a digital picture player, a digital video recorder, a digital video player, a device capable of transmitting and receiving data in a wireless environment, one of a variety of electronic devices that constitute a home network, one of a variety of electronic devices that constitute a computer network, one of a variety of electronic devices that constitute a telematics network, a radio frequency identification (RFID) device, or one of a variety of electronic devices that constitute a computing system.

It should be understood that example embodiments described herein should be considered in a descriptive sense only and not for purposes of limitation. Descriptions of features or aspects within each device or method according to example embodiments should typically be considered as available for other similar features or aspects in other devices or methods according to example embodiments. While some example embodiments have been particularly shown and described, it will be understood by one of ordinary skill in the art that variations in form and detail may be made therein without departing from the spirit and scope of the claims.

1. A semiconductor package, comprising:
a mounting board;
a first semiconductor chip on the mounting board, the first semiconductor chip having a first peripheral area, a second peripheral area, and a central area between the first and second peripheral areas, the central area including penetrating electrodes and first pads, the penetrating electrodes penetrating the central area, the first pads on and electrically connected to the penetrating electrodes, respectively;
a second semiconductor chip on the first peripheral area, the second semiconductor chip including a second pad on a top surface thereof;
a third semiconductor chip on the second peripheral area, the third semiconductor chip including a third pad on a top surface thereof;
conductive wirings extending from the second and third pads, respectively, the conductive wirings electrically connected to the penetrating electrodes, respectively.
a plurality of first heat dissipation terminals being between the mounting board and the first peripheral area of the first semiconductor chip, the plurality of first heat dissipation terminals not being in connection with the penetrating electrodes; and
a plurality of second heat dissipation terminals being between the mounting board and the second peripheral area of the first semiconductor chip, the plurality of second heat dissipation terminals not being in connection with the penetrating electrodes.

2. The semiconductor package of claim 1, wherein:
the first, second, and third semiconductor chips have a first length, a second length, and a third length, respectively, in a lengthwise direction; and
the second and third lengths each are shorter than the first length.

3. The semiconductor package of claim 2, wherein a sum of the second and third lengths equals the first length.

4. The semiconductor package of claim 1, wherein the top surfaces of the second and third semiconductor chips are on a same plane.

5. The semiconductor package of claim 1, wherein at least one first conductive wiring from among the conductive wirings extends from the second pad along the top surface and a sidewall of the second semiconductor chip.

6. The semiconductor package of claim 1, wherein the second semiconductor chip further includes a rewiring layer, which extends from a bottom surface of the second pad.

7. The semiconductor package of claim 1, wherein part of the second semiconductor chip does not overlap the first semiconductor chip.

8. The semiconductor package of claim 1, wherein the second and third semiconductor chips include no through silicon vias therein.

9. A semiconductor package, comprising:
a mounting board;
a first semiconductor chip on the mounting board, the first semiconductor chip having a first peripheral area, a second peripheral area, and a central area between the first and second peripheral areas, the central area of the first semiconductor chip including penetrating electrodes and first pads, the penetrating electrodes penetrating the first semiconductor chip, and the first pads on and electrically connected to the penetrating electrodes, respectively;
second and third semiconductor chips on the first semiconductor chip, the second and third semiconductor chips spaced apart from each other to expose the first pads therebetween, the second and third semiconductor chips being devoid of through silicon vias;
conductive wirings electrically connecting the first, second, and third semiconductor chips;
a plurality of first heat dissipation terminals being between the mounting board and the first peripheral area of the first semiconductor chip, the plurality of first heat dissipation terminals not being in connection with the penetrating electrodes; and
a plurality of second heat dissipation terminals being between the mounting board and the second peripheral area of the first semiconductor chip, the plurality of second heat dissipation terminals not being in connection with the penetrating electrodes.

10. The semiconductor package of claim 9, wherein:
the first, second, and third semiconductor chips have a first length, a second length, and a third length, respectively, in a lengthwise direction; and
the second and third lengths each are shorter than the first length.

11. The semiconductor package of claim 10, wherein a sum of the second and third lengths equals the first length.

12. The semiconductor package of claim 9, wherein top surfaces of the second and third semiconductor chips are on a same plane.

13. The semiconductor package of claim 9, wherein at least one first conductive wiring from among the conductive wirings extends from a second pad of the second semiconductor chip along a top surface and a sidewall of the second semiconductor chip.

14. The semiconductor package of claim 9, wherein the second semiconductor chip further includes a rewiring layer, which extends from a bottom surface of a second pad of the second semiconductor chip.

15. The semiconductor package of claim 9, wherein part of the second semiconductor chip does not overlap the first semiconductor chip.

16. A semiconductor package, comprising:
a mounting board;
a first semiconductor chip on the mounting board, the first semiconductor chip having a first peripheral area, a second peripheral area, and a central area between the first and second peripheral areas, the first semiconductor chip including both penetrating electrodes and first pads at the central area thereof, the penetrating electrodes electrically connecting the mounting board to the first semiconductor chip, the first pads on and electrically connected to the penetrating electrodes, respectively;
at least one second semiconductor chip and at least one third semiconductor chip on the first semiconductor chip, the second semiconductor chip including a second pad on a top surface thereof, the third semiconductor chip including a third pad on a top surface thereof, the second and third semiconductor chips spaced apart from each other to expose the central area of the first semiconductor chip;
conductive wirings respectively extending from the second and third pads, the conductive wirings respectively electrically connecting the second and third pads to the penetrating electrodes,
a plurality of first heat dissipation terminals being between the mounting board and the first peripheral area of the first semiconductor chip, the plurality of first heat dissipation terminals not being in connection with the penetrating electrodes; and
a plurality of second heat dissipation terminals being between the mounting board and the second peripheral area of the first semiconductor chip, the plurality of second heat dissipation terminals not being in connection with the penetrating electrodes.

17. The semiconductor package of claim 16, wherein a first number of the conductive wirings extend along the top surfaces and a sidewall of the second semiconductor chip, and a second number of the conductive wirings extend along the top surface and sidewall of the third semiconductor chip.

18. The semiconductor package of claim 16, wherein the at least one second semiconductor chip further includes a rewiring layer, which extends from a bottom surface of the second pad.

19. (canceled)

20. The semiconductor package of claim 16, wherein the least one second semiconductor chip includes a plurality of second semiconductor chips, and the plurality of second semiconductor chips are stacked on the first semiconductor chip such that the plurality of second semiconductor chips are aligned with each other without forming any stepped structure on sides of a stacked structure of the plurality of second semiconductor chips.
